(19) United States
(12) Patent Application Publication
(10) Pub. No.: US 2025/0120203 A1
(43) Pub. Date: Apr. 10, 2025

(54) IMAGE SENSING MODULE

(71) Applicant: TONG HSING ELECTRONIC INDUSTRIES, LTD., Taipei City (TW)

(72) Inventors: Jui-Hung Hsu, Taipei City (TW); Li-Chun Hung, Taipei City (TW)

(73) Assignee: TONG HSING ELECTRONIC INDUSTRIES, LTD., Taipei City (TW)

(21) Appl. No.: 18/526,468

(22) Filed: Dec. 1, 2023

(30) Foreign Application Priority Data
Oct. 4, 2023 (TW) 112138167

(51) Int. Cl. H01L 27/146

(52) U.S. Cl. CPC H10F 39/804

(57) ABSTRACT

An image sensing module is provided. The image sensing module includes an image sensor chip, a support member, a transparent layer, and a shielding layer. The support member is arranged on upper surface of the image sensor chip and surrounds an image sensing region of the image sensor chip. The transparent layer is arranged on upper surface of the support member. Lower surface of the transparent layer faces the image sensor chip, and includes a transparent region and a shielding region surrounding the transparent region. The transparent region corresponds to the image sensing region. Projection of the shielding region in normal direction of the lower surface of the transparent layer does not overlap with the image sensing region. The shielding layer is formed on the shielding region, and includes a frame portion and a plurality of reinforcing portions. The reinforcing portions are individually located at corners of the frame portion.

### CROSS-REFERENCE TO RELATED APPLICATION

This non-provisional application claims priority under 35 U.S.C. § 119 (a) to patent application Ser. No. 11/213,8167 filed in Taiwan, R.O.C. on Oct. 4, 2023, the entire contents of which are hereby incorporated by reference.

### BACKGROUND

### Technical Field

The present disclosure relates to an image sensing module, and in particular, to a packaging structure of an image sensing module.

### Related Art

In a traditional packaging structure of an image sensor chip, a glass layer is fixed to the image sensor chip by adhesive, and the adhesive is surrounded around a periphery of the image sensor chip. However, when the light enters the packaging structure and irradiates an element other than the image sensor, the light may be focused at a specific position in the image sensing region of the image sensor due to reflection or refraction, resulting in a flare problem. In order to solve the above flare problem, opaque sealant may be arranged on side surfaces of the glass layer and the adhesive to prevent external light from entering inside of the packaging structure through the adhesive on the side surface of the packaging structure, and a rectangular black matrix is arranged between the contact surface of the glass layer and the adhesive to prevent the external light from passing through the glass layer on an incident plane of the packaging structure and irradiating the adhesive or another element other than the image sensor.

With the increasing demand for enhanced sensing ability of the image sensor in the market, there remains an expectation to maintain or even reduce the volume of the packaging structure. In the existing image sensor packaging structures, the image sensing region is ever expanding while an adhesive layer is ever shrinking, which results in a continuous decrease in a distance between the image sensing region and the adhesive layer, making the impact of the flare problem increasingly difficult to ignore. Through experiments, it is found that the cause of the flare problem is at least partly due to a fact that the traditional black matrix cannot completely shield the adhesive with the miniaturization of the packaging structure.

### SUMMARY

In view of this, the present disclosure provides an image sensing module, including an image sensor chip, a support member, a transparent layer, and a shielding layer. The image sensor chip includes an image sensing region. The support member is arranged on an upper surface of the image sensor chip and surrounds the image sensing region. The transparent layer is arranged on an upper surface of the support member. The transparent layer includes an upper surface and a lower surface. The lower surface faces the image sensor chip and includes a transparent region and a shielding region surrounding the transparent region. The transparent region corresponds to the image sensing region, and a projection of the shielding region in a normal direction of the lower surface of the transparent layer does not overlap with the image sensing region. The shielding layer is formed on the shielding region of the lower surface of the transparent layer and located between the transparent layer and the support member. The shielding layer includes a frame portion and a plurality of reinforcing portions, and the reinforcing portions are individually located at corners of the frame portion.

### BRIEF DESCRIPTION OF THE DRAWINGS

FIG. 1A is a schematic top view of an image sensing module without a transparent layer according to an embodiment of the present disclosure.

FIG. 1B is a schematic cross-sectional view in a tangential direction of X1-X1 according to an embodiment of FIG. 1A of the present disclosure.

FIG. 1C is a partially enlarged schematic diagram of a framed portion A according to an embodiment of FIG. 1A of the present disclosure.

FIG. 2A is a schematic top view of an image sensing module according to a first embodiment of the present disclosure.

FIG. 2B is a schematic cross-sectional view in a tangential direction of X2-X2 according to an embodiment of FIG. 2A of the present disclosure.

FIG. 3 is a schematic top view of an image sensing module according to a second embodiment of the present disclosure.

FIG. 4 is a schematic top view of an image sensing module according to a third embodiment of the present disclosure.

FIG. 5 is a schematic top view of an image sensing module according to a fourth embodiment of the present disclosure.

### DETAILED DESCRIPTION

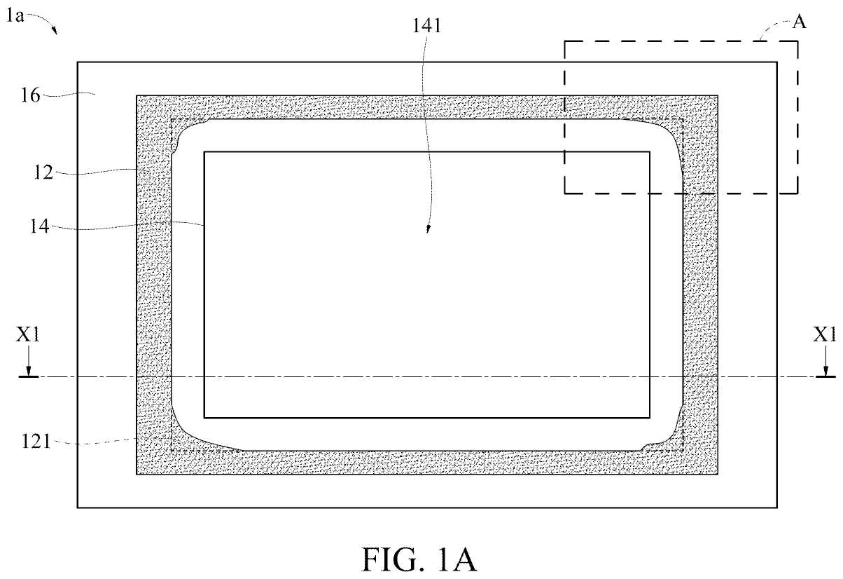

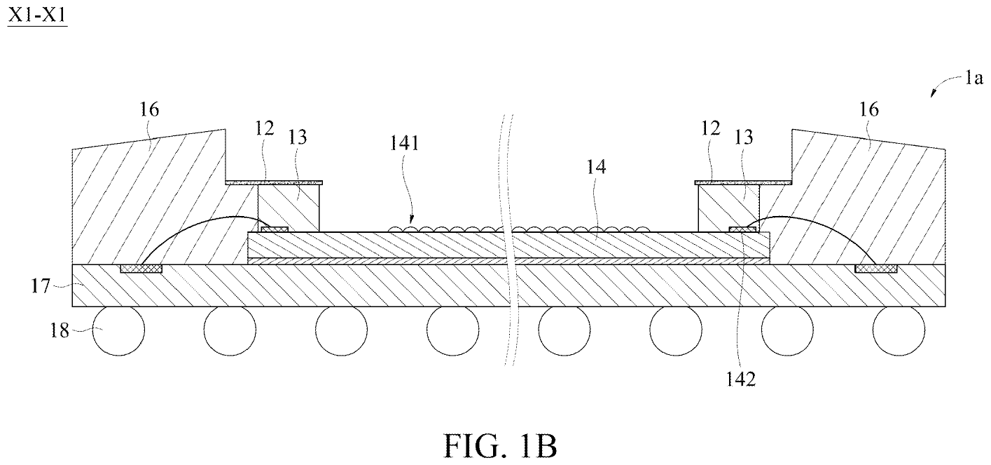

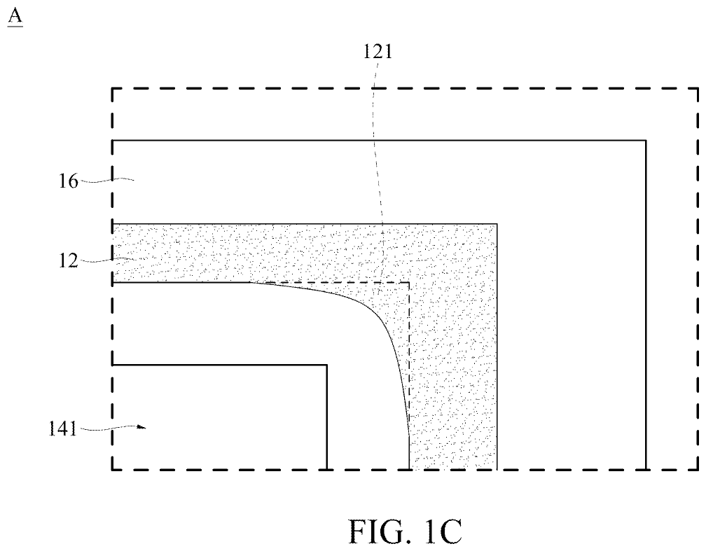

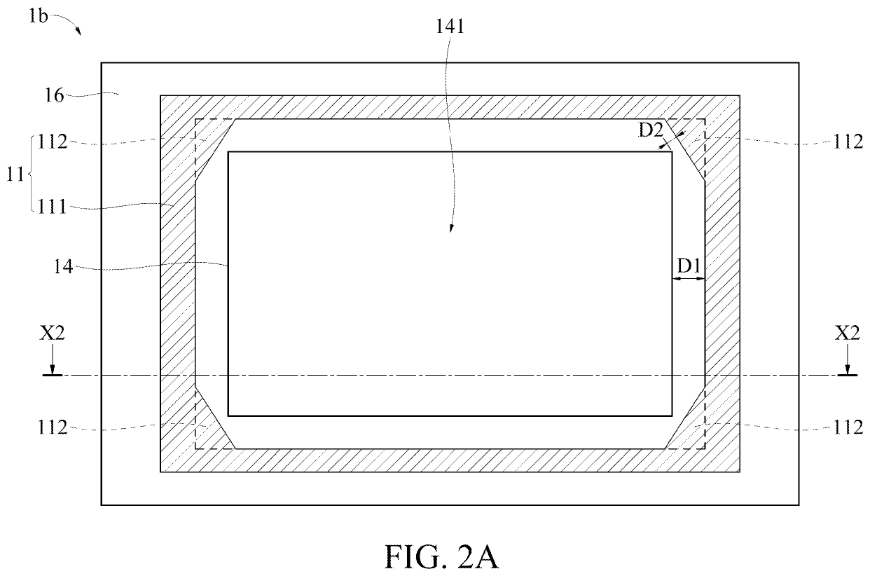

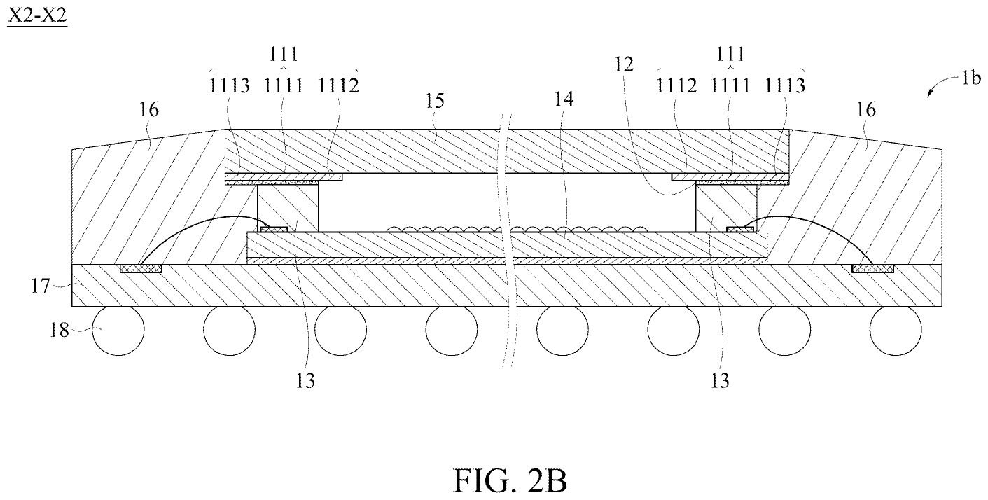

FIG. 1A is a schematic top view of an image sensing module without a transparent layer according to an embodiment of the present disclosure. FIG. 1B is a schematic cross-sectional view in a tangential direction of X1-X1 according to an embodiment of FIG. 1A of the present disclosure. Please refer to FIG. 1A and FIG. 1B. An image sensing module la includes an adhesive layer 12, a support member 13, an image sensor chip 14, a packaging layer 16, a substrate layer 17, and solder contacts 18. In this embodiment, the image sensing module la is in an unsealed state as the transparent layer 15 (see FIG. 2B) has not been mounted. Therefore, the adhesive layer 12 and the image sensor chip 14 inside the image sensing module 1A can be directly seen from the top view of FIG. 1a. The image sensor chip 14 includes an image sensing region 141 and is arranged on an upper surface of the substrate layer 17. The support member 13 is arranged on an upper surface of the image sensor chip 14 and surrounds the image sensing region 141. The adhesive layer 12 is arranged on an upper surface of the support member 13 and surrounds the image sensing region 141. The packaging layer 16 is arranged on the upper surface of the substrate layer 17 and surrounds the adhesive layer 12, the support member 13, and the image sensor chip 14.

The image sensor chip 14 is an integrated circuit chip, which may be a COMS image sensor chip 14 for visible light or non-visible light. The image sensor chip 14 may be connected to the substrate layer 17 through flip-chip connection or wire bonding. The substrate layer 17 may include a plurality of solder contacts 18, which are adapted to bond the image sensing module la to an electronic element (not shown), so that the image sensor chip 14 arranged on the substrate layer 17 is electrically connected to the electronic element. The substrate layer 17 may be made of resin (or a mixture of the resin and glass fiber), ceramic, or glass. In some embodiments, a material of the substrate layer 17 may be one of a plurality of ceramic materials selected from the group consisting of silicon nitride (Si₃N₄), alumina (Al₂O₃), aluminum nitride (AlN), zirconia (ZrO₂), zirconia toughened alumina (ZTA), and beryllium oxide (BeO), or a combination thereof.

An upper side and a lower side of the support member 13 are respectively used to connect the transparent layer 15 and the image sensor chip 14, and the support member 13 keeps a distance between the transparent layer 15 and the image sensor chip 14. In this embodiment, the upper surface of the image sensor chip 14 includes a bonding pad 142. The bonding pad 142 is buried under a bottom of the support member 13 and electrically connected to the substrate layer 17 through wire bonding. In another embodiment, the bonding pad 142 on the upper surface of the image sensor chip 14 may alternatively be arranged on an outer side of the support member 13. The support member 13 surrounds the image sensing region 141 to form a closed space between the image sensor chip 14 and the transparent layer 15, which only allows light to enter the image sensing module from the transparent layer 15. A material of the support member 13 may be one of a plurality of materials selected from the group consisting of polyurethane (PU), polyacrylonitrile (PAN), polyvinyl alcohol (PVA), polylactide (PLA), polyethylene oxide (PEO), polyethylene terephthalate (PET), polyvinyl pyrrolidone (PVP), polyvinyl chloride (PV), cellulose acetate (CA), poly(lactic-co-glycolic acid) (PLGA), polycaprolactone (PCL), polyethylene glycol (PEG), polydimethylsiloxane (PDMS), glass fiber, PS, PMMA, PA, and PA 6.6, or a combination thereof. A material of the transparent layer 15 may be one of a plurality of materials selected from the group consisting of poly (methyl methacrylate) (PMMA), polystyrene (PS), polycarbonate (PC), allyl diglycol carbonate (CR-39), acrylonitrile-styrene copolymer (SAN), poly(4-methyl-1-pentene) (TPX), and polyamide (PA), or a combination thereof.

The packaging layer 16 may be made of epoxy, polyimide (PI), or silicone, serving to enclose and protect the image sensing region 141 on its inner side and preventing moisture from permeating into the enclosed space of the image sensing module. In addition, the packaging layer may be formed as an opaque barrier to prevent external light from passing through the packaging layer 16 and causing photosensitive interference. The packaging layer 16 may be formed by a potting process, so that an uncured high-fluidity colloid covers the structure to be packaged.

The adhesive layer 12 is arranged around the image sensing region 141 to fix the transparent layer 15 and the support member 13. As shown in FIG. 1A, the adhesive layer 12 is substantially shaped like a square frame surrounding the image sensing region 141. The adhesive layer 12 may be formed by an adhesive dispensing process to allow the sealing adhesive to cover the support member 13 around the image sensing region 141. In detail, the support member 13 is arranged on the upper surface of the image sensor chip 14, and a nozzle of an adhesive dispensing device moves along a frame direction of the support member 13 to apply the sealing adhesive. During research, the applicant found that when the adhesive dispensing device alters its movement direction, the adhesive is prone to whirl as a result of pulling of the adhesive dispensing nozzle. For example, as shown in FIG. 1A, whirling occurs at four corners of a frame of the adhesive layer 12.

FIG. 1C is a partially enlarged schematic diagram of a framed portion A according to an embodiment of FIG. 1A of the present disclosure. Refer to FIG. 1C. A corner of an inner included angle of the adhesive layer 12 is not a 90-degree corner, but has a whirling portion 121 in a shape of an umbrella, which causes the adhesive layer 12 to be closer to the image sensing region 141 at the corner. In some embodiments, a shielding layer may be arranged between the adhesive layer 12 and the transparent layer 15 to prevent light from penetrating through the transparent layer 15 and irradiating the adhesive layer 12. However, the shielding layer in the shape of a square frame prevents light from irradiating the frame portion of the adhesive layer 12, but cannot prevent light from irradiating the whirling portion 121 at the corner of the frame of the adhesive layer 12. Therefore, the corner section of the image sensing region 141 is affected by the light reflected from the whirling portion 121, potentially leading to the flare problem.

FIG. 2A is a schematic top view of an image sensing module according to a first embodiment of the present disclosure. FIG. 2B is a schematic cross-sectional view in a tangential direction of X2-X2 according to an embodiment of FIG. 2A of the present disclosure. Please refer to FIG. 2A and FIG. 2B. An image sensing module 1b includes a shielding layer 11, an adhesive layer 12, a support member 13, an image sensor chip 14, a transparent layer 15, a packaging layer 16, a substrate layer 17, and solder contacts 18, and is in a sealed state. The transparent layer 15 includes an upper surface and a lower surface, and the lower surface of the transparent layer 15 faces the image sensor chip 14 and includes a transparent region and a shielding region surrounding the transparent region. The transparent region is correspondingly arranged over the image sensing region 141 of the image sensor chip 14, and a projection of the shielding region in a normal direction of the lower surface of the transparent layer 15 does not overlap with the image sensing region 141. In other words, when light is emitted from directly above the image sensing module 1b toward the transparent layer 15, only the light passing through the transparent region can reach the image sensing region 141. The shielding layer 11 is formed on the shielding region on the lower surface of the transparent layer 15 and is located between the transparent layer 15 and the support member 13. The transparent layer 15 and the shielding layer 11 are bonded to form a black matrix glass, and the black matrix glass is bonded to the support member 13 through the adhesive layer 12.

The shielding layer 11 is adapted to block light of a specific wavelength. For example, the image sensor chip 14 is a visible light image sensor, and the image sensing module may be provided with a shielding layer 11 that blocks light of a visible light wavelength (ranging from 380 nm to 780 nm). The shielding layer 11 includes a frame portion 111 and a plurality of reinforcing portions 112. The frame portion 111 is arranged above the support member 13 to prevent light from irradiating the support member 13 or the adhesive layer 12. The reinforcing portions 112 are individually located at corners of the frame portion 111. The corner may be an inner included angle of a corner section of the frame portion 111. In the first embodiment, four corners of the frame portion 111 are provided with reinforcing portions 112. In another embodiment, the reinforcing portion 112 may be selectively arranged at one or more of the four corners of the frame portion 111. In addition, the frame portion 111 is not limited to a rectangle. The reinforcing portion 112 of the shielding layer 11 prevents the light from irradiating a whirling portion 121 at the corner of the frame of the adhesive layer 12, thereby avoiding occurrence of the flare problem at a corner portion of the image sensing region 141. As described above, the whirling portion 121 of the adhesive layer 12 is substantially in the shape of an umbrella, that is, a hypotenuse of a triangle is recessed toward a vertex angle to form a geometric shape having an arc line. In the first embodiment, the reinforcing portion 112 of the shielding layer 11 extends inward from the corner of the frame portion 111 to form a triangle, and the hypotenuse portion thereof protrudes inward (closer to the image sensing region 141) relative to the arc line portion of the whirling portion 121 in the shape of an umbrella, so as to prevent light from irradiating an inner edge of the whirling portion 121. In this embodiment, the transparent region of the transparent layer 15 is substantially in the shape of an octagon, and a projection of a transparent region of the octagon in the normal direction of the lower surface of the transparent layer 15 completely covers the image sensing region 141. In other words, the frame portion 111 and the plurality of reinforcing portions 112 of the shielding layer 11 are all located on an outer side of the image sensing region 141.

One advantage of the triangular reinforcing portion 112 is that it is easy to form, and only needs to retain corner blocks during the process of cutting the shielding layer 11. In some embodiments, the appearance of the whirling portion 121 of the adhesive layer 12 is related to viscosity of the sealing adhesive and a movement speed and direction of an adhesive dispensing device, and unrelated to a length or a width of an outer frame portion of the support member 13. Therefore, the whirling portion 121 is substantially in the shape of a symmetrical umbrella. Based on this, the reinforcing portion 112 is designed as an isosceles triangle to achieve the maximum shielding effect. In some embodiments, a distance between a border of each reinforcing portion 112 of the shielding layer 11 and a border of the image sensing region 141 is less than a distance between a border of the frame portion 111 of the shielding layer 11 and the border of the image sensing region 141. The distance may be a shortest linear distance between boundaries or a distance between projections projected on the upper surface of the image sensor chip 14. For example, a distance between the border of the frame portion 111 of the shielding layer 11 and the border of the image sensing region 141 is a length D1, and a distance between the border of the reinforcing portion 112 of the shielding layer 11 (that is, any point on the hypotenuse of the triangle) and the border of the image sensing region 141 is a length D2, where the length D1 is greater than the length D2. In this way, the reinforcing portion 112 extends inward relative to the corner of the frame portion 111, which is enough to cover the whirling portion 121 of the adhesive layer 12 that protrudes inward.

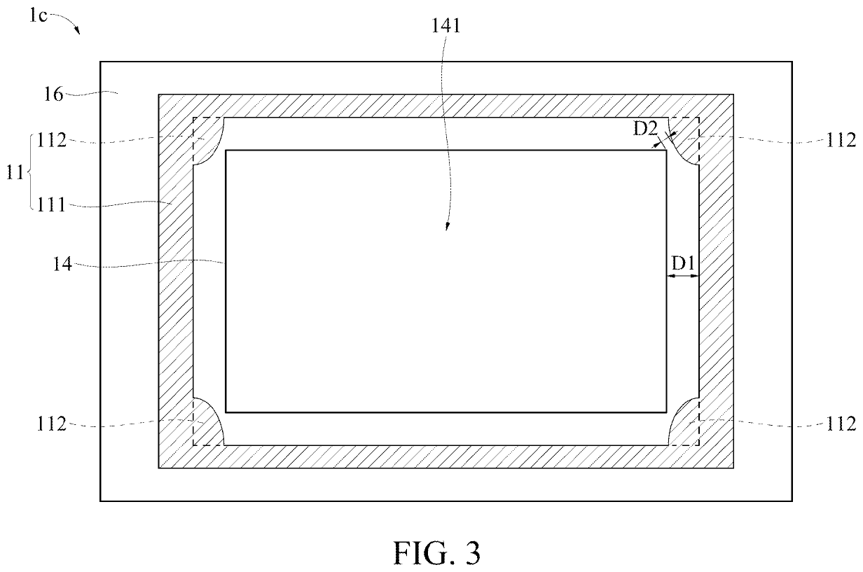

A difference between the length D1 and the length D2 depends on a degree of protrusion of the whirling portion 121. The use of low viscosity sealing adhesive may lead to more serious whirling problem of the adhesive layer 12 at the corner portion. In this case, it is beneficial to increase the coverage by using the shielding layer 11 with a relatively large difference between the length D1 and the length D2. For example, FIG. 3 is a schematic top view of an image sensing module according to a second embodiment of the present disclosure. Refer to FIG. 3. In a second embodiment, a reinforcing portion 112 of a shielding layer 11 of an image sensing module 1c extends inward from a corner of a frame portion 111 to form a sector, and an arc line portion thereof protrudes inward relative to an arc line portion of a whirling portion 121 in a shape of an umbrella, so as to prevent light from irradiating an inner edge of the whirling portion 121. The arc line portion of the reinforcing portion 112 of the sector protrudes more inward relative to the hypotenuse portion of the triangular reinforcing portion 112, thereby increasing the difference between the length D1 and the length D2 to achieve a better corner covering effect. The sector is not limited to a geometric shape formed by an arc line and two straight lines having a same radius, but also a geometric shape formed by an arc line and two straight lines having different lengths. For example, the sector shown in FIG. 3 includes two straight lines having different lengths. In another embodiment, the reinforcing portion 112 is designed as a sector with equal radius to improve the shielding effect.

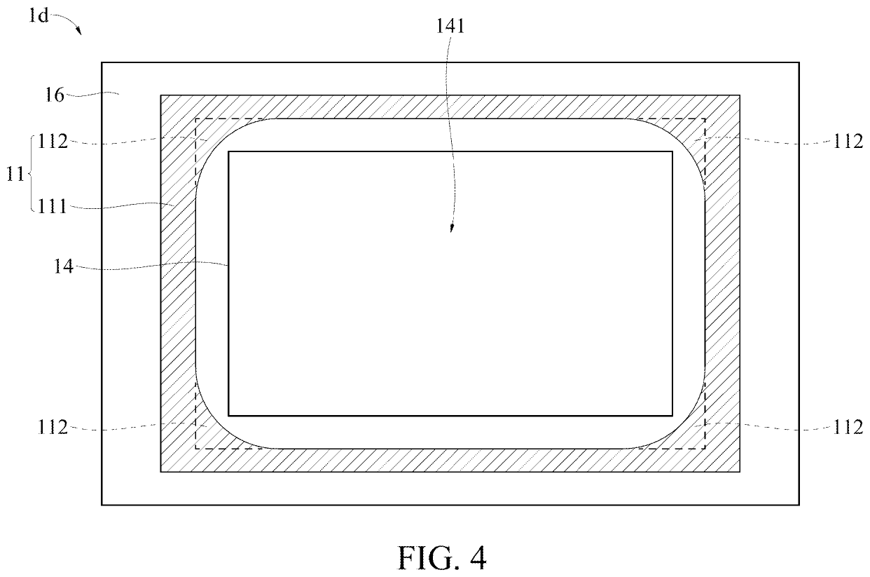

Increasing the protruding degree of the reinforcing portion 112 helps to shield the whirling portion 121. However, when the frame portion 111 of the shielding layer 11 is relatively close to the image sensing region 141 (that is, the length D1 is relatively short), employing a more pronounced protrusion in the reinforcing portion 112 may cause the corner portion of the image sensing region 141 to be covered, resulting in occurrence of shadows at corners of an image. Therefore, a size of the image sensing region 141 should be considered for selection of the structure of the reinforcing portion 112. In order to give consideration to the coverage of the reinforcing portion 112 and expand the range of the image sensing region 141, in some embodiments, the reinforcing portion 112 extends inward from the corner of the frame portion 111 to form a shape of an umbrella. For example, FIG. 4 is a schematic top view of an image sensing module according to a third embodiment of the present disclosure.

Refer to FIG. 4. In the third embodiment, a reinforcing portion 112 of a shielding layer 11 of an image sensing module 1d forms a shape of an umbrella, and an arc line portion thereof is aligned with or slightly protrudes inward relative to an arc line portion of a whirling portion 121 in a shape of an umbrella, so as to prevent light from irradiating an inner edge of the whirling portion 121. The shape of an umbrella may be a geometric shape formed by two straight lines and an arc line that is formed by recessing a hypotenuse of a triangle inward toward a vertex angle. Lengths of the two straight lines may be same or different.

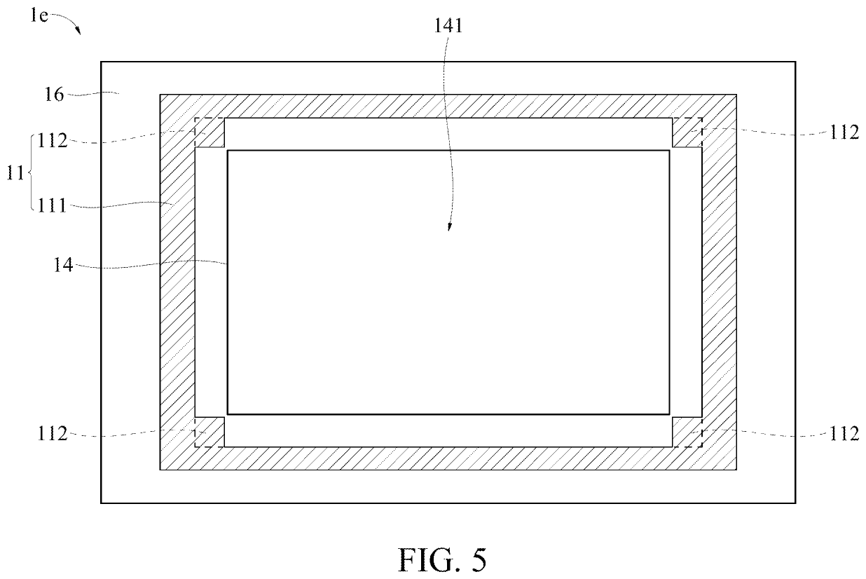

In some embodiments, considering that it is difficult to control the protruding degree of the whirling portion 121, using a large area of reinforcing portion 112 is helpful to ensure that the whirling portion 121 is covered. For example, FIG. 5 is a schematic top view of an image sensing module according to a fourth embodiment of the present disclosure. Refer to FIG. 5. In the fourth embodiment, a reinforcing portion 112 of a shielding layer 11 of an image sensing module le extends inward from a corner of a frame portion 111 to form a rectangle, and an inner angle of the rectangle protrudes inward relative to an arc line portion of a whirling portion 121 in a shape of an umbrella, so as to prevent light from irradiating an inner edge of the whirling portion 121. The reinforcing portion 112 of the rectangle can ensure that the whirling portion 121 does not exceed a coverage region of the shielding layer 11 to the greatest extent, but also limits the range of the image sensing region 141. The inner angle of the rectangle may be greater than or equal to 90 degrees, and lengths of two straight lines forming the inner angle may be same or different.

In some embodiments, the frame portion 111 of the shielding layer 11 includes an overhead shielding section. The overhead shielding section is arranged directly above the support member 13, and the reinforcing portion 112 extends inward from the corner of the frame portion 111. In this embodiment, the overhead shielding section covers directly above the support member 13, and the reinforcing portion 112 is suspended and protrudes inward. In this way, when the light is projected onto the shielding layer 11 from directly above the image sensing module, the overhead shielding section prevents the light from irradiating the adhesive layer 12 or the support member 13, and the reinforcing portion 112 prevents the light from irradiating the whirling portion 121 of the adhesive layer 12.

In some other embodiments, the frame portion 111 of the shielding layer 11 includes an overhead shielding section and an inner side shielding section. The overhead shielding section is arranged directly above the support member 13, the inner side shielding section extends inward from the overhead shielding section, and the reinforcing portion 112 extends inward from a corner of the inner side shielding section of the frame portion 111. In this embodiment, the overhead shielding section is attached directly above the support member 13, and the inner side shielding section and the reinforcing portion 112 are suspended and protrude inward. For example, referring to FIG. 2B, the frame portion 111 of the shielding layer 11 of the image sensing module 1b of the first embodiment includes an overhead shielding section 1111, an inner side shielding section 1112, and an outer side shielding section 1113. The inner side shielding section 1112 extends inward from the overhead shielding section 1111, and the outer side shielding section 1113 extends outward from the overhead shielding section 1111. The inner side shielding section 1112 is beneficial to prevent obliquely incident light from irradiating the adhesive layer 12 or the support member 13, the reinforcing portion 112 prevents the light from irradiating the whirling portion 121 of the adhesive layer 12 in a normal direction or an inclined direction, and the outer side shielding section 1113 prevents the light from irradiating the outer packaging layer 16.

Based on the above, the shielding layer 11 of the image sensing module includes a frame portion 111 and a plurality of reinforcing portions 112. The reinforcing portions 112 are individually located at corners of the frame portion 111. In this way, the reinforcing portion 112 is sufficient to cover the whirling portion 121 formed at the corner of the adhesive layer 12 by an adhesive dispensing device. The reinforcing portion 112 is arranged to provide a larger turning space for dispensing the adhesive layer 12 and prevents the adhesive layer 12 at the corner from exceeding the shielding region of the shielding layer 11. In addition, the reinforcing portion 112 allows the adhesive layer 12 to have more coating space at the corner, which improves reliability of the structure. In some embodiments, the present disclosure provides different shapes of reinforcing portions 112 to be used during designing of the shielding layer 11, so as to provide the ability of the shielding layer 11 to cover the whirling portion 121 of the adhesive layer 12 or to prevent the shielding layer 11 from covering the range of the image sensing region 141.

It should be understood that the terms “upper”, “lower”, “inner”, and “outer” used in the present disclosure are only used to describe the technical content of the embodiments of the present disclosure or relative relationships of elements, and are not used to limit the absolute positional relationship of elements in space during implementation of the present disclosure. Although the present disclosure is disclosed in the above embodiments, the embodiments recorded in the specification and drawings are not intended to limit the present disclosure. A person with ordinary knowledge in the technical field can make some changes and refinements without departing from the spirit and scope of the present disclosure. The protection scope of the present disclosure shall be subject to the scope defined by the attached patent claims.

What is claimed is:

1. An image sensing module, comprising:
an image sensor chip, comprising an image sensing region;
a support member, arranged on an upper surface of the image sensor chip and surrounding the image sensing region;
a transparent layer, arranged on an upper surface of the support member, wherein the transparent layer comprises an upper surface and a lower surface, the lower surface faces the image sensor chip and comprises a transparent region and a shielding region surrounding the transparent region, the transparent region corresponds to the image sensing region, and a projection of the shielding region in a normal direction of the lower surface of the transparent layer does not overlap with the image sensing region; and
a shielding layer, formed on the shielding region of the lower surface of the transparent layer and located between the transparent layer and the support member, wherein the shielding layer comprises a frame portion and a plurality of reinforcing portions, and the reinforcing portions are individually located at corners of the frame portion.

2. The image sensing module according to claim 1, wherein the plurality of reinforcing portions extend inward from the corners of the frame portion to form a triangle.

3. The image sensing module according to claim 2, wherein the triangle is an isosceles triangle.

4. The image sensing module according to claim 1, wherein the plurality of reinforcing portions extend inward from the corners of the frame portion to form a sector.

5. The image sensing module according to claim 1, wherein the plurality of reinforcing portions extend inward from the corners of the frame portion to form a shape of an umbrella.

6. The image sensing module according to claim 1, wherein the plurality of reinforcing portions extend inward from the corners of the frame portion to form a rectangle.

7. The image sensing module according to claim 1, wherein a distance between a border of each reinforcing portion and a border of the image sensing region is less than a distance between a border of the frame portion and the border of the image sensing region.

8. The image sensing module according to claim 1, wherein the frame portion comprises an overhead shielding section and an inner side shielding section, the overhead shielding section is arranged over the support member, and the inner side shielding section extends inward from the overhead shielding section.

9. The image sensing module according to claim 1, further comprising a packaging layer, wherein the packaging layer is configured to surround the transparent layer, the support member, and a side surface of the image sensor chip.

10. The image sensing module according to claim 1, further comprising an adhesive layer, wherein the adhesive layer is between the transparent layer and the support member, and comprises a frame portion and a plurality of whirling portions, and the projection of the shielding layer in the normal direction of the lower surface of the transparent layer overlaps with the frame portion and the plurality of whirling portions.
